(19) United States
(12) Patent Application Publication
(10) Pub. No.: US 2024/0264018 A1
(43) Pub. Date: Aug. 8, 2024

(54) CONNECTOR CONTACT FORCE SENSING

(71) Applicant: Arista Networks, Inc., Santa Clara, CA (US)

(72) Inventors: Matthew Moe, San Jose, CA (US); Youngbae Park, Milpitas, CA (US); Robert Wilcox, Saratoga, CA (US); Richard Hibbs, Carmel-by-the-Sea, CA (US)

(21) Appl. No.: 18/164,154

(22) Filed: Feb. 3, 2023

(51) Int. Cl. G01L 5/00; G01R 1/067; G06F 13/40; H01R 11/01; H05K 5/00; H05K 5/02

(52) U.S. Cl. CPC G01L 5/0052; G01R 1/06727; G06F 13/40; H01R 11/01; H05K 5/0018; H05K 5/0204; G06F 2213/0026

(57) ABSTRACT

A contact force sensing device may be configured to mate with a port connector having a plurality of conductive contact structures. The contact force sensing device may include a base and a force sensor on the base. The force sensor may be configured to measure a force applied by a first conductive contact structure in the plurality of conductive contact structures using a sensor probe that contacts the first conductive contact structure when the sensor probe is inserted into the port connector. The contact force sensing device may include a mating connector surrogate structure that flanks the sensor probe and is configured to contact at least a second conductive contact structure in the plurality of conductive contact structures when the sensor probe contacts the first conductive contact structure.

### BACKGROUND

A mating connection between two components can be made by corresponding connectors on the two components. The first connector can include pins, pads, or other structures that contact corresponding structures of the second connector to provide the desired connection between the two components. The contact can be characterized by an amount of contact force that provides a satisfactory connection.

### BRIEF DESCRIPTION OF THE DRAWINGS

FIG. 1 is a diagram of an illustrative system having components that are coupled to each other by a mating connection in accordance with some embodiments.

FIG. 2 is a perspective view of an illustrative port configured to receive a mating connector in accordance with some embodiments.

FIG. 3 is a side view of an illustrative port connector of the type shown in FIG. 2 in accordance with some embodiments.

FIG. 4 is a diagram of illustrative connector contact sensing equipment configured to perform contact force sensing in accordance with some embodiments.

FIG. 5 is a top view of an illustrative connector contact force sensing device in accordance with some embodiments.

FIG. 6 is a cross-sectional side view of an illustrative connector contact force sensing device of the type shown in FIG. 5 in accordance with some embodiments.

FIG. 7 is a side view of an illustrative sensor probe inserted into a port in the absence of a flanking surrogate structure in accordance with some embodiments.

FIG. 8 is a side view of an illustrative sensor probe inserted into a port in the presence of a flanking surrogate structure in accordance with some embodiments.

FIG. 9 is a diagram of an illustrative connector contact force sensing device having multiple sensor probes for sensing contact forces applied in opposing directions in accordance with some embodiments.

FIG. 10 is a diagram of an illustrative connector contact force sensing device having multiple sensor probes for sensing contact forces applied in parallel directions in accordance with some embodiments.

### DETAILED DESCRIPTION

Electrical components may be coupled to each other using corresponding connectors. As an example, a first connector may form a port configured to receive (mate) with second connector. When the second connector mates with the first connector, corresponding contact structures of the first and second connectors may engage each other to provide a desired degree (magnitude) of contact force (e.g., a surface normal contact force in some arrangements) therebetween. This contact force may be critical to providing a satisfactory (physical and therefore electrical) connection between the two connectors.

It may be desirable to obtain information (e.g., performance metrics) characterizing the contact force applied by contact structures of one connector on contact structures of the other connector. However, the characterization of this contact force can be difficult. As an example, the port connector may typically be housed within an interior cavity of an enclosure (e.g., a cage) and therefore may be difficult to access after system assembly, thereby making testing of the contact force(s) applied by the port connector difficult, especially in the field or after system deployment. Furthermore, even if measurements of the port connector were to be taken by test equipment, without simulating the insertion of the actual mating connector into the port connector, measurements on the contact force applied by port connector may still be inaccurate. While the contact force can be indirectly characterized (e.g., inferred) by, for example, analyzing the electrical performance of the connection, this indirect characterization may be unreliable as multiple parameters other than the contact force can be responsible for the electrical performance.

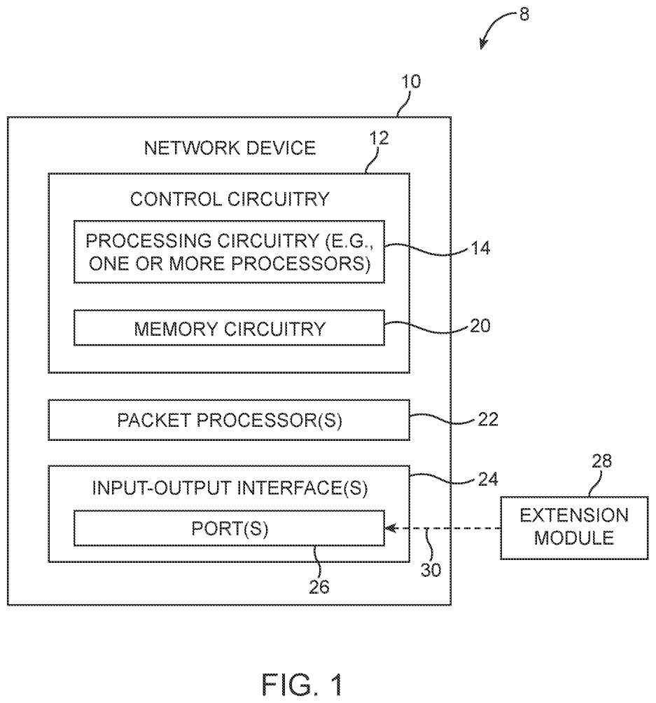

Accordingly, it may be desirable to provide one or more types of devices (e.g., connector contact sensing equipment) as described herein to detect the contact force as applied by one or more contact structures in a connector, directly and accurately. Configurations in which the connector to be measured by the contact force sensing device is a port connector within a networking system are sometimes described herein as an illustrative example. However, the connector to be measured by the contact force sensor device(s) may encompass various types of connectors existing in other types of systems (e.g., more generally in computing systems, electrical systems, etc.). An illustrative system having a port with a connector to be measured by the contact force sensor device is shown in FIG. 1, as an example.

In the example of FIG. 1, an illustrative system 8 may include one or more network devices 10. Each network device 10 may be a switch (e.g., a multi-layer L2/L3 switch), a router or gateway, a bridge, a hub, a repeater, a firewall, a wireless access point, a device serving other networking functions, a device that includes a combination of these functions, or other types of network devices. Multiple such network device 10 (e.g., of different types or having different functions) in system 8 may be present and interconnected therebetween and with other network devices in other network portions to form a communications network that forwards traffic (e.g., packets) between end hosts.

Network device 10 may include control circuitry 12 having processing circuitry 14 and memory circuitry 20, one or more packet processors 22, and input-output interfaces 24 disposed within a housing of network device 10. The housing may include an exterior cover (e.g., a plastic exterior shell, a metal exterior shell, or an exterior shell formed from other rigid or semi-rigid materials) that provides structural support and protection for the components of network device 10 mounted within the housing. In one illustrative arrangement, network device 10 may be or form part of a modular network device system (e.g., a modular switch system having removably coupled modules usable to flexibly expand the capabilities such as ports, specialized functionalities, etc., of the modular switch system). In another illustrative arrangement, network device 10 may be a fixed-configuration network device (e.g., a fixed-configuration switch having a fixed number of ports and/or a fixed hardware configuration).

Processing circuitry 14 may include one or more processors or processing units based on central processing units (CPUs), based on graphics processing units (GPUs), based on microprocessors, based on general-purpose processors, based on host processors, based on microcontrollers, based on digital signal processors, based on programmable logic devices such as a field programmable gate array device (FPGA), based on application specific system processors (ASSPs), based on application specific integrated circuit (ASIC) processors, and/or based on other processor architectures.

Processing circuitry 14 may run (e.g., execute) a network device operating system and/or other software/firmware that is stored on memory circuitry 20. Memory circuitry 20 may include non-transitory (tangible) computer readable storage media that stores the operating system software and/or any other software code, sometimes referred to as program instructions, software, data, instructions, or code. As an example, network device control plane functions may be stored as (software) instructions on the non-transitory computer-readable storage media (e.g., in portion(s) of memory circuitry 20 in network device 10). The corresponding processing circuitry (e.g., one or more processors of processing circuitry 14 in network device 10) may process or execute the respective instructions to perform the corresponding operations. Memory circuitry 20 may be implemented using non-volatile memory (e.g., flash memory or other electrically-programmable read-only memory configured to form a solid-state drive), volatile memory (e.g., static or dynamic random-access memory), hard disk drive storage, and/or other storage circuitry. Processing circuitry 14 and memory circuitry 20 as described above may sometimes be referred to collectively as control circuitry 12 (e.g., implementing a control plane of network device 10).

In particular, processing circuitry 14 may execute network device control plane software such as operating system software, routing policy management software, routing protocol agents or processes, routing information base agents, and other control software, may be used to support the operation of protocol clients and/or servers (e.g., to form some or all of a communications protocol stack such as the TCP/IP stack), may be used to support the operation of packet processor(s) 22, may store packet forwarding information, may execute packet processing software, and/or may execute other software instructions that control the functions of network device 10 and the other components therein.

Packet processor(s) 22 may be used to implement a data plane or forwarding plane of network device 10. Packet processor(s) 22 may include one or more processors or processing units based on central processing units (CPUs), based on graphics processing units (GPUs), based on microprocessors, based on general-purpose processors, based on host processors, based on microcontrollers, based on digital signal processors, based on programmable logic devices such as a field programmable gate array device (FPGA), based on application specific system processors (ASSPs), based on application specific integrated circuit (ASIC) processors, and/or based on other processor architectures.

Packet processor 22 may receive incoming data packets via input-output interfaces 24, parse and analyze the received data packets, process the packets based on packet forwarding decision data (e.g., in a forwarding information base) and/or in accordance with network protocol(s) or other forwarding policy, and forward (or drop) the data packet accordingly. The packet forwarding decision data may be stored on a portion of memory circuitry 20 and/or other memory circuitry integrated as part of or separate from packet processor 22.

Input-output interfaces 24 may include communication interface components such as an Ethernet interface (e.g., one or more Ethernet ports), an optical interface, a Bluetooth interface, a Wi-Fi interface, and/or other networking interfaces for connecting network device 10 to the Internet, a local area network, a wide area network, a mobile network, other portions of the communications network, and/or to other network device(s), peripheral devices, and/or other computing equipment (e.g., host equipment, user equipment, etc.).

As shown in FIG. 1, input-output interfaces 24 may include one or more ports 26 having connectors (sometimes referred to herein as port connectors or sockets) to which corresponding mating connectors of external components can be physically coupled and electrically connected. Ports 26 may have different form-factors to accommodate different cables, different modules, different devices, or generally different external equipment.

In the example of FIG. 1, one or more ports 26 may each be configured to receive an extension or expansion module 28. Extension module 28 may be inserted or plugged into port 26 as indicated by arrow 30. Extension module 28 may include (electrical or optical) transceiver modules such as pluggable (e.g., removable) transceiver modules (e.g., small form-factor pluggable (SFP) modules, quad small form-factor pluggable (QSFP) modules, QSFP double density module (QSFP-DD) modules, octal small form-factor pluggable (OSFP) modules, etc.) or other network interface modules, may include removable network modules that expands the functionalities of network device 10 (e.g., an asynchronous transfer mode network module, an Ethernet network module, a router or virtual private network module, a network services module, a route processor module, etc.), or may include any other suitable modules. In particular, an optical or electrical transceiver module, when plugged into or received in port 26, may enable network device 10 to be coupled to another network device 10 through a (high-speed) fiber-optic or a copper cable.

In other illustrative arrangements, one or more components such as packet processor 22 may be omitted from device 10 and device 10 may generally be a computing device with other non-networking functions. In other words, port 26 may be contained within a non-networking computing device 10 or generally an electrical device that conveys electrical signals using port 26 with external equipment.

Configurations in which ports 26 include port connectors configured to receive and mate with an edge card connector of a transceiver module are sometimes described herein an illustrative example. In other illustrative examples, ports 26 may include other types of port connectors configured to mate with edge card connectors for other components (e.g., components utilizing Peripheral Component Interconnect (PCI) connectors, Peripheral Component Interconnect Express (PCIE) connectors, accelerated graphics port (AGP) connectors, etc.) and/or other types of port connectors configured to mate with non-edge-card connectors (e.g., any mating connectors to which the corresponding port connectors apply a contact normal force when in the inserted or connected state).

While contact force sensing devices are sometimes described herein to measure a contact normal force applied by contact structures in a connector for port 26, this is merely illustrative. Contact force sensing devices described herein may generally be configured (e.g., assembled with a specific form-factor) to measure the contact force applied by various types of connectors (e.g., generally, a connector that applies a contact normal force to the mating connector when in the connected state). These connectors for which contact force is measured may be present in any system (e.g., generally, an electrical system in which electrical signals are conveyed through the connected connectors).

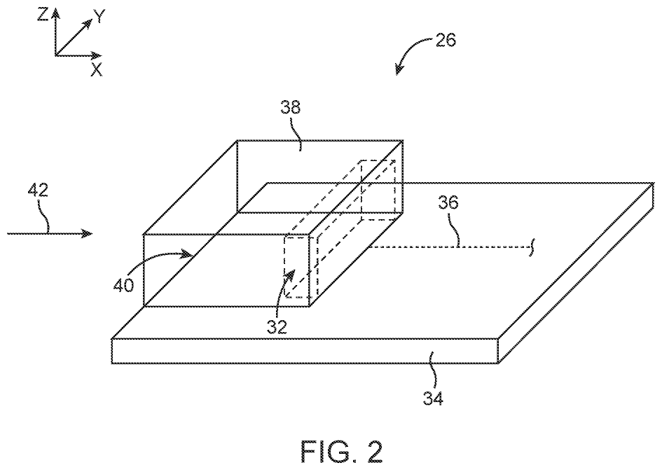

An illustrative type of port having a connector for which contact force is measured is shown in FIG. 2. In the example of FIG. 2, port 26 may be configured to receive module 28 (e.g., containing an edge card). Port 26 may include port connector 32 (e.g., an edge card socket) mounted to (e.g., soldered onto) substrate 34 such as a printed circuit substrate. Port 26 may be disposed along edge 40 of substrate 34 or elsewhere on substrate 34. Substrate 34 may include signal paths 38 (e.g., conductive metal traces forming a bus or other types of signal paths) conveying signals between connector 32 (and therefore any module inserted into port 26) to the other portions of the host system (e.g., other components on network device 10 in FIG. 1 such as processing circuitry 14, memory circuitry 20, packet processor 22, other input-output components, etc.).

Connector 32 may be placed within an enclosure such as enclosure 38 (sometimes referred to herein as cage 38). Cage 38 may be attached to substrate 34 and may define a cavity region having an opening along edge 40 of substrate 34. Module 28 or other external equipment containing a mating connector may be inserted (in direction 42) into the cavity region through the opening along edge 40. When module 28 is inserted into port 26, a mating connector on module 28 may be inserted into connector 32 of port 26. Cage 38 may serve as a guide to receive the module and assist in alignment and therefore connection between the module connector (e.g., an edge card on module 28) and port connector 32 (e.g., a corresponding edge card socket). If desired, other guide and alignments structures may be included (instead of or in addition to cage 38). If desired, in other configurations, cage 38 may be omitted.

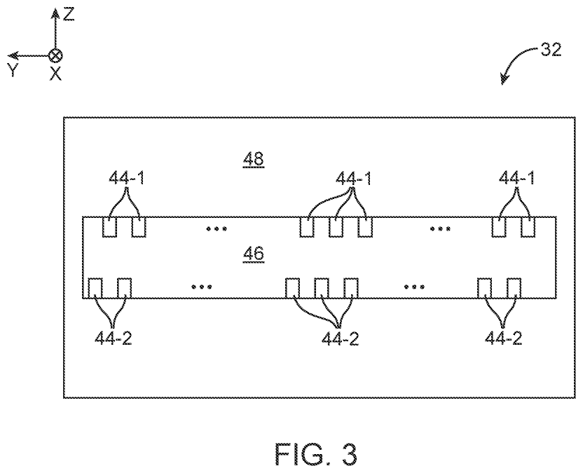

FIG. 3 is a side view of a port connector such as connector 32 when viewed in direction 42 (FIG. 2). In particular, FIG. 3 shows illustrative contact structures 44 (referring to structures 44-1 and 44-2). Contact structures 44 may be electrically conductive contact pins or other electrically conductive structures configured to make contact with corresponding electrically conductive contact structures such as electrically conductive contact pads of a mating connector inserted into opening 46 of connector 32 (e.g., when module 28 is inserted into port 26). The contacting structures of the mating connectors used to make physical connections may in turn form electrical connections therebetween as well.

A first row of contact structures 44-1 may be provided along the top edge of opening 46 and a second row of contact structures 44-2 may be provided along the bottom edge of opening 46. Connector 32 may include a dielectric housing or enclosure 48 (e.g., over-molded plastic) that surrounds and defines opening 46. Biasing structure in enclosure 48 and coupled to contact structures 44 may enable contact forces to be applied by contact structures 44 when a corresponding mating connector is inserted within opening 46 to partially displace and deflect overlapping contact structures 44.

As an example, when the top row of contact pins 44-1 is deflected in the +z direction by an inserted matching connector having corresponding contact pads facing contact pins 44-1, contact pins 44-1 may each apply a force on a corresponding contact pad at least partially in the −z direction (sometimes referred to herein as a contact normal force). As another example, when the bottom row of contact pins 44-2 is deflected in the −z direction by an inserted matching connector having corresponding contact pads facing contact pins 44-2, contact pins 44-2 may each apply a force on a corresponding contact pad at least partially in the +z direction (sometimes referred to herein as a contact normal force).

Issues may arise between the mating connectors that leads to an unreliable physical contact and therefore an unreliable electrical connection between a port connector and a module connector inserted into the port. As an example, an insufficient amount of contact normal force may be applied by contact pins of an edge card socket on contact pads of the edge card when inserted, thereby adversely affecting the electrical connection and data transmission through the electrical connection. Additionally, due to the placement of the port connector (e.g., within a cage and/or any other enclosure structures), it may be difficult to directly obtain measurements on the contact normal force and/or pinpoint the issue of unreliability to insufficient contact normal force.

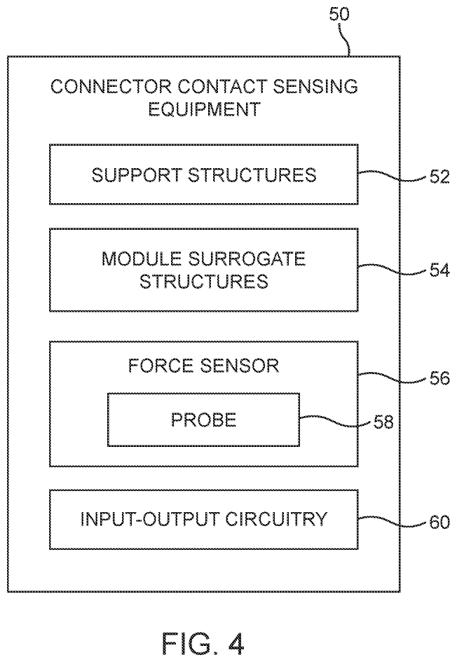

Accordingly, to provide a direct and easily deployable mechanism that measures connector contact force, portable connector contact sensing equipment (e.g., portable test equipment) such as a handheld contact force sensing device may be provided. FIG. 4 is a functional block diagram of illustrative connector contact sensing equipment 50. Equipment 50 may sometimes be referred to herein as test equipment 50, connector contact force sensor 50, or connector contact sensing device or simply device 50.

As shown in FIG. 4, device 50 may include one or more support structures 52 that support internal components of device 50, that house internal components of device 50, and/or that provide other structural functions for device 50. Support structure 52 may include housing structures such as a case, an enclosure, a cover, a frame, a base, etc., and/or may include interior support structures such as substrate layers (e.g., printed circuit substrates), support layers, etc. Portions of these housing and interior support structures may be attached to one another using adhesive, fasteners, and/or any other suitable attachment structures. Support structures 52 may be formed from any combination of suitable materials (e.g., dielectrics such as plastics and polymers, metals, etc.).

Device 50 may further include one or more force sensors such as force sensor 56. Force sensor 56 may be configured to measure the contact normal force using one or more sensor probes 58. As examples, force sensors 56 may include one or more of a load cell based force sensor (e.g., having a strain gauge load cell, an inductive load cell, a capacitive load cell, a hydraulic load cell and/or other types of load cells that convert an applied force detected at sensor probe 58 into an electrical signal), a strain gauge or force sensing resistor sensor (e.g., where sensor probe 58 forms part of the strain gauge and/or implements the forcing sensing element) that exhibits varying electrical resistances (as output) depending on the applied force, an optical force sensor, an ultrasonic force sensor, and any other types of force sensors.

Configurations in which sensor probe 58 includes a cantilever beam coupled to a load cell to implement force sensor 56 are sometimes described herein as an illustrative example. In particular, sensor probe 58 may be similar in pitch to a contact pin whose applied force is measured and/or may be similar in dimensions to a contact pad to which the contact pin is intended to apply the contact force. In this configuration, sensor probe 58 and therefore force sensor 56 may be used to measure the normal force applied by a single contact pin (e.g., one of contact structures 44-1 or one of contact structures 44-2 in FIG. 3). The load cell coupled to sensor probe 58 may convert the force applied by a single contact pin into a corresponding electrical signal. Because improper contact at just a single contact pin or generally a single contact structure may adversely impact the electrical connection or data transmission at the port connector, measurements taken by sensor probe 58 in this configuration may be helpful to pinpoint even single contact pin issues.

If desired, device 50 may include multiple (e.g., two, three, more than three) instances of force sensor 56, each configured to measure contact force at a different contact pin or generally connector contact structure using a corresponding sensor probe 58.

Device 50 may include structures that help simulate a connector contact normal force as the port connector would actually apply to a corresponding mating connector being inserted into port 26. Accordingly, device 50 may include surrogate structure 54 that simulate module structures (e.g., of module 28), edge card structures (e.g., in scenarios where port 26 includes an edge card socket), or generally structures of external equipment normally being inserted into port 26 to establish an electrical connection. Surrogate structures may sometimes be referred to herein as a module surrogate structure, an edge card surrogate structure, or generally a matching connector surrogate structure based on the type of structures surrogate structures 54 are intended to simulate. Surrogate structures 54 may be formed using portions support structures 52 such as a substrate layer, a housing, a base, etc.

Surrogate structures 54 and/or support structures 52 may provide device 50 with exterior dimensions (e.g., a length, a width, and/or a height) to help facilitate device 50 being inserted into port 26 in a similar manner as how module 28 would be inserted into port 26 (e.g., as described in connection with FIG. 3). In particular, surrogate structures 54 and/or support structures 52 may have the same dimensions, rigidity, materials, and/or other characteristics as corresponding portions of module 28 that interact with port 26, thereby properly simulating a more accurate contact normal force applied by the tested pin (as if module 28 were inserted instead of device 50). Configured in this manner, device 50 may more accurately measure the contact normal force applied by the tested contact pin of port 26 (e.g., the measured contact normal force is a more accurate representation of that experienced by the connector of module 28 when inserted into port 26).

Device 50 may also include input-output circuitry 60 that interfaces between internal components such as forces sensor 56 and external components such as external equipment and/or a user. As a first example, circuitry 60 may include an output device such as a display or other visual output devices. The display may provide a visual output indicative of force measurements gathered by force sensor 56 (e.g., force sensor data) to a user. As a second example, circuitry 60 may include input-output interfaces (e.g., ports) configured to connect device 50 to external equipment (e.g., external computing equipment that analyzes the sensor data, an external monitor or display that displays the sensor data, etc.). In other words, sensor data gathered by force sensor 56 may be supplied to the external equipment via these interfaces for storage and/or further analysis. As a third example, circuitry 60 may include input devices (e.g., buttons) that receive user input (e.g., to begin gathering sensor data, to stop the gathering of sensor data, to determine which sensor data to display in configurations where device 50 includes multiple force sensors, etc.). As a fourth example, the input-output interfaces of circuitry 60 may be configured to receive commands, updates, and/or other data or information from external equipment based on which the sensing operations of force sensor(s) 56 are performed. These examples are merely illustrative.

Device 50 may omit some of these components and/or may include other components, if desired. In some illustrative arrangements, device 50 may include processing circuitry (e.g., one or more processors of the same type described in connection with processing circuitry 14 in FIG. 1), memory circuitry (e.g., one or more types of memory described in connection with memory circuitry 20 in FIG. 1) configured to store the sensor data, power management circuitry, power storage components such as a battery, data busses or other signal paths interconnecting electrical components in device 50, etc.

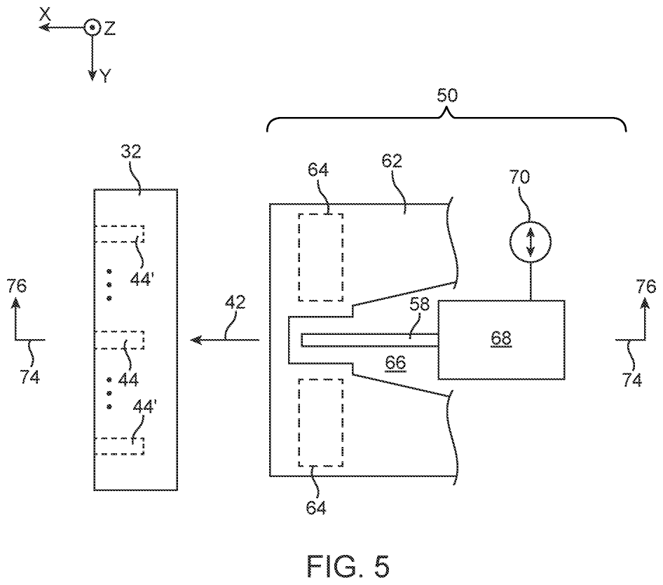

FIG. 5 is a top view of an illustrative portion of connector contact sensing equipment 50 (e.g., device 50) of the type described in connection with FIG. 4. As shown in FIG. 5, device 50 includes sensor probe 58 implemented as a cantilever beam having a distal end suspended in air (e.g., in air gap 66) and a proximal end attached to load cell 68. Sensor probe 58 may include an underlying substrate (e.g., a printed circuit substrate) similar to an edge card and/or conductive traces or a conductive contact pad formed on the underlying substrate. If desired, sensor probe 58 may be attached to other types of force sensor components in other (non-load-cell) sensor arrangements.

Support structures 52 (FIG. 4) of device 50 may include a platform or layer 62 (e.g., a printed circuit substrate layer, a plastic frame, etc.). Layer 62 may be co-planar with probe 58 but may be separated from sensor probe 58 by an air gap 66, thereby suspending a portion of sensor probe 58. Layer 62 may include portions 64 flanking opposing sides of sensor probe 58 at its distal end. Portions 64 may form a surrogate structure 54 (FIG. 4) for device 50 (e.g., mimicking characteristics of an edge card such as material, rigidity, thickness (as measured along the z-axis), etc.).

Sensor probe 58 and portions 64 may be inserted (in direction 42) into connector 32 as device 50 is inserted into port 26 containing connector 32 (e.g., into cage 38 not explicitly shown in FIG. 5). When inserted, device 50 may form a (physical) connection with connector 32 in a manner similar to when a mating connector is inserted into port 26 to form a physical and electrical connection with connector 32.

In the inserted state, sensor probe 58 may overlap (along the z-axis) and make contact with a given contact structure 44 (e.g., a top contact structure 44-1 or a bottom contact structure 44-2 in FIG. 3) of connector 32. In particular, sensor probe 58 may partially displace and deflect contact structure 44 (along the z-axis) such that contact structure 44 applies a contact force (e.g., a contact normal force parallel to the z-axis) on sensor probe 58. This force applied by contact structure 44 may be detected by load cell 68 and converted into an electrical or other type of output signal, thereby producing force sensor data indicative of the applied force.

Surrogate structure 54 (FIG. 4) formed from portions 64 of layer 62 may further overlap other contact structures 44′ (e.g., the remaining top contact structures 44-1 and/or the remaining bottom contact structures 44-2) whose applied forces are not measured by probe 58 and load cell 68. However, portions 64 may also partially displace and deflect corresponding contact structures 44′ (along the z-axis) such that contact structure 44′ also apply corresponding contact forces (e.g., contact normal forces parallel to the z-axis) on portions 64.

In the example of FIG. 5, sensor probe 58 may be configured (e.g., disposed along a central axis parallel x-axis) to measure the contact force applied by a central contact structure 44 while portions 64 forming a surrogate structure overlap all other peripheral contact structures 44′ on both sides of central contact structure 44. In other words, contact structure 44 is shown in FIG. 5 to be in a central region of the row of contact structures, while contact structures 44′ are shown in FIG. 5 to be in the peripheral regions of the row of contact structures. However, this is merely illustrative. If desired, sensor probe 58 may be configured to measure a different (non-central) contact structure (e.g., measured contact structure 44 may be offset from the middle but still in the central region of the row of contact structures, may be an edge contact structure in one of the peripheral regions of the row of contact structures, etc.), and portions 64 forming the surrogate structure may still overlap the remaining unmeasured contact structures 44′.

Because sensor probe 58 should be precisely aligned with the corresponding contact structure 44 whose applied force is being measured, device 50 may include a positioner such as positioner 70 coupled to sensor probe 58 and/or load cell 68 (e.g., the entire force sensing assembly or just the sensor probe 58). Positioner 70 may adjust (e.g., fine-tune) the position of sensor probe 58 based on user input. As examples, positioner 70 may be implemented using an electrically-adjustable positioner (e.g., that receives electrical signals to control the state of the positioner), may be implemented using a fastener (e.g., a screw may be loosened such that the position of the sensor probe 58 can be adjusted), etc. Positioner 70 may generally adjust the relative position of sensor probe 58 (e.g., relative to support structures such as layer 62 of device 50) along one or more of an x-axis, a y-axis, and a z-axis.

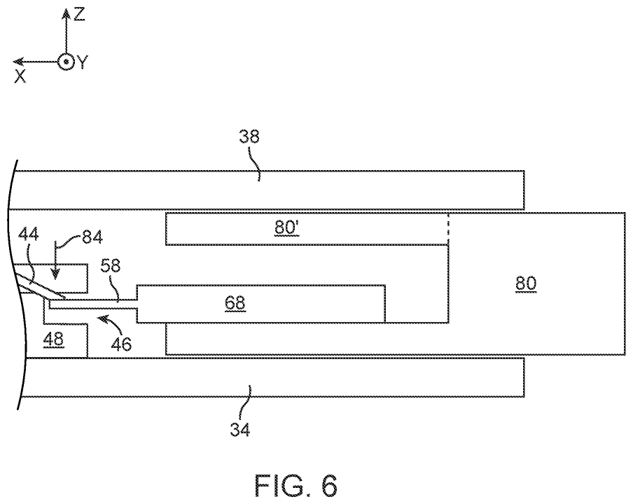

FIG. 6 is a cross-sectional side view (e.g., taken along line 74 and viewed in direction 76 in FIG. 5) of connector contact sensing equipment 50 (e.g., device 50) of the type described in connection with FIG. 5 when device 50 is inserted into port 26 (FIG. 2). While FIG. 5 omits some of the housing and enclosure structures of device 50 and port 26 in order not to obscure the features shown in FIG. 5, FIG. 6 includes these structures.

As shown in FIG. 6, device 50 may include support structure 80, which is sometimes referred to herein as a base, base layer, or base structure (e.g., forming support structures 52 in FIG. 4). Support structure 80 may include multiple layers that are assembled (e.g., adhered together by adhesive, fastened together by fasteners, and/or assembled in other manners). If desired, layer 62 (FIG. 5) may form a portion of support structure 80. A portion of support structure 80 may be provided underneath and support the force sensing assembly (e.g., a sensor probe and load cell). In the example of FIG. 6, a portion of support structure 80 may extend beyond port 26 (e.g., beyond cage 38) and form a handheld portion of device 50.

In general, device 50 may have a housing (e.g., a form-factor) that mimics the housing of module 28 (e.g., at the portions of module 28 that interact with cage 38, substrate 34, connector 32, alignment structure, or other portions of port 26). In other words, a housing (e.g., formed by support structure 80 and/or other portions of support structures 52) may have similar dimensions (e.g., a same height along the z-axis, a same width along a y-axis, and/or a same length along an x-axis) as module 28. In particular, as shown in FIG. 6, support structure 80 may define a bottom exterior surface of device 50 adjacent to a bottom interior surface of port 26 and a top exterior surface of device 50 adjacent to a top interior surface of port 26. While not explicitly shown in FIG. 6, support structure 80 may also include portions defining exterior side surfaces of device 50 (e.g., opposing parallel surfaces in the x-z plane) adjacent to respective interior side surfaces of port 26. Configured in this manner, support structure 80 (or other support structures of device 50) may define a form-factor that enables insertion and mating with port 26 (e.g., cage 38 and/or substrate 34).

If desired, in some illustrative arrangements (e.g., arrangements in which portion 80′ is omitted from support structure 80), some exterior surfaces of device 50 may not be adjacent to corresponding interior surfaces of port 26. If desired, device 50 may include (e.g., as part of support structure 80) alignment features or structures (e.g., stops, posts, etc.) configured to facilitate proper insertion into port 26 and/or port connector 32.

When device 50 is inserted into port 26, sensor probe 58 will be inserted into opening 46 of connector 32 to displace and deflect a corresponding contact structure 44 in the +z direction. Accordingly, contact structure 44 may apply a force 84 in the direction parallel to the surface normal of sensor probe 58. Load cell 68 may sense force 84 to produce a sensor output signal (e.g., having a magnitude proportional to the magnitude of force 84. The electrical signal may be conveyed to processing circuitry and/or input-output circuitry such as a display. As an example, the processing circuitry may be enclosed by support structure 80 while the display may be disposed on exterior surface of support structure 80 (e.g., in a position visible to a user).

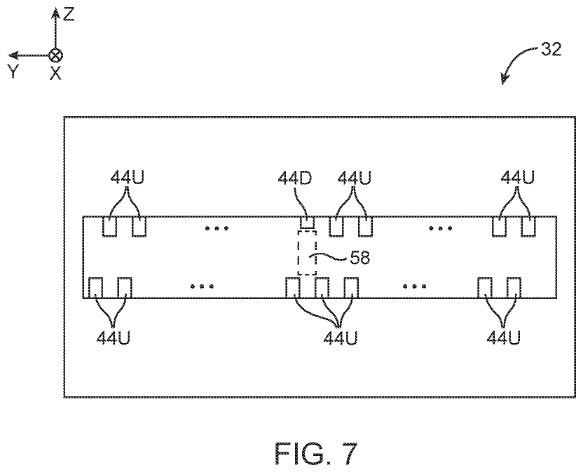

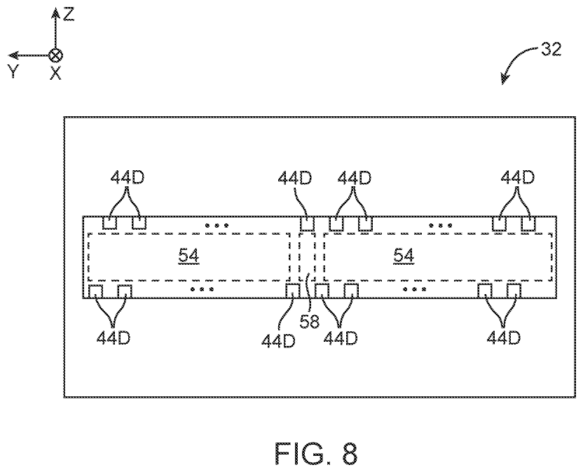

In the examples of FIGS. 5 and 6, an illustrative row of contact structures 44 and 44′ are shown and described. These contact structures may be a top row of contact structures 44-1 (FIG. 3) or a bottom row of contact structures 44-2 (FIG. 3) in connector 32. If desired, connector 32 may include only a single (top or bottom) row of contact structures or may include two (top and bottom) rows of contact structures. Illustrative arrangements of how sensor probe 58 and/or surrogate structures 54 (e.g., layer portions 64 in FIG. 5) interact with top and bottom rows of contact structures are shown in FIGS. 7 and 8.

In an illustrative configuration shown in FIG. 7, a device 50 having a single probe 58 but omits surrogate structures (e.g., portions 64 in FIG. 5) may displace and deflect a single contact (pin) structure 44D. However, device 50 even when inserted into port 26 may not displace the remaining contact structures 44U. Accordingly, device 50 (in the configuration of FIG. 7) may not provide an accurate measurement of the contact normal force being applied by contact structure 44D because device 50 does not simulate the actual connection of module 28. As an example, an actual edge card of module 28 being inserted into connector 32 will displace all of the contact structure 44D and 44U. However, device 50 in the configuration of FIG. 7 does not. This discrepancy in the number of displaced contact structures can cause a discrepancy in the contact normal force applied even at a single contact structure, leading to a less accurate contact normal force measurement.

In contrast, as shown in FIG. 8, device 50 (e.g., of the type described in connection with FIGS. 4-6) having a single probe 58 and surrogate structure 54 (e.g., portions 64 in FIG. 5) may displace and deflect all contact structure 44D, even if only the contact normal force of one of the contact pins is measured by sensor probe 58. Because all contact structures 44D of connector 32 are displaced by probe 58 and surrogate structure 54, a more accurate representation of the actual connection of module 28 is simulated. Accordingly, the contact normal force applied by a single (e.g., central) contact structure 44D on sensor probe 58 is more accurate compared to the configuration described in connection with FIG. 7.

While FIGS. 5-8 show device 50 with a single sensor probe 58 for sensing the contact normal force of a single contact structure 44, this is merely illustrative. If desired, device 50 may include multiple sensor probes 58 each configured to detect the contact normal force of a different contact structure 44.

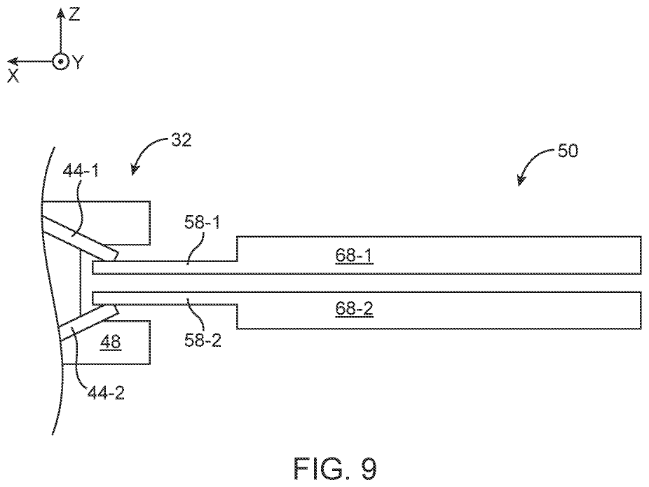

In the example of FIG. 9, device 50 may include a first sensor probe 58-1 (e.g., a first cantilever beam) and a second sensor probe 58-2 (e.g., a second cantilever beam). Sensor probe 58-1 may displace and deflect a contact structure 44-1 in the top row of contact structures in connector 32 when inserted into connector 32. Accordingly, the contact structure 44-1 may apply a contact normal force in the −z direction, which is detected by sensor probe 58-1 and load cell 68-1. Sensor probe 58-2 may displace and deflect a contact structure 44-2 on the bottom row of contact structures in connector 32 when inserted into connector 32. Accordingly, the contact structure 44-2 may apply a contact normal force in the +z direction, which is detected by sensor probe 58-2 and load cell 68-2.

Configured in this manner, device 50 in FIG. 9 may allow for simultaneous measurements of contact normal forces for two contact structures (e.g., contact pins) during a single insertion event. The two contact structures for which the contact normal forces are measured apply contact normal forces in opposing directions (e.g., are in different top and bottom rows of the contact structures). As such, probe 58-1 and 58-2 may lie along different parallel x-y planes. Probe 58-1 and 58-2 may not exactly overlap along the z-axis as the measured contact structures 44-1 and 44-2 may also not exactly overlap along the z-axis.

While not explicitly shown in the cross-sectional view of FIG. 9, device 50 may include some of the same features described in connection with FIGS. 4-8 (e.g., surrogate structures 54 flanking both sides of both probes 58-1 and 58-2, a base or support structure 80, input-output circuitry, processing circuitry, etc.).

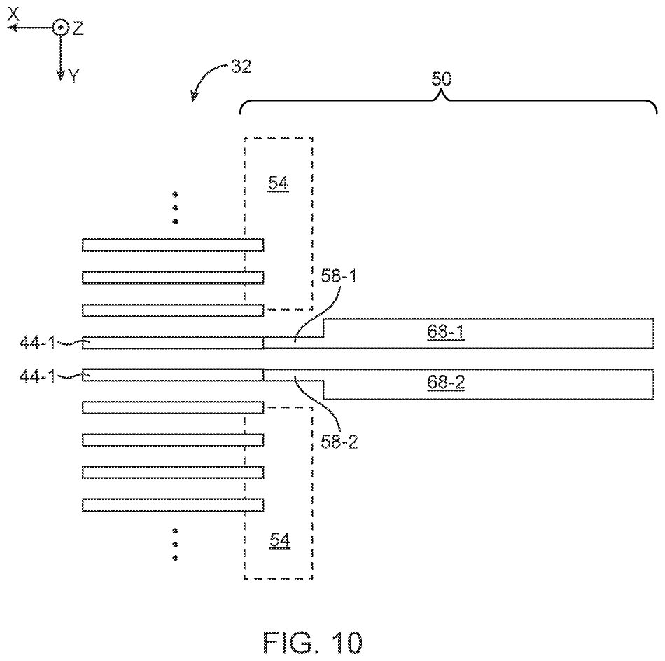

In the example of FIG. 10, device 50 may also include a first sensor probe 58-1 (e.g., a first cantilever beam) and a second sensor probe 58-2 (e.g., a second cantilever beam). Sensor probe 58-1 may displace and deflect a first contact structure 44-1 on the top row of contact structures in connector 32 when inserted into connector 32. Accordingly, the first contact structure 44-1 may apply a contact normal force in the −z direction, which is detected by sensor probe 58-1 and load cell 68-1. Sensor probe 58-2 may displace and deflect a second contact structure 44-1 on the top row of contact structures in connector 32 when inserted into connector 32. Accordingly, the second contact structure 44-1 may apply a contact normal force in the −z direction, which is detected by sensor probe 58-2 and load cell 68-2.

Configured in this manner, device 50 in FIG. 10 may allow for simultaneous measurement of contact normal forces for two contact structures (e.g., contact pins) during a single insertion event. The two contact structures for which the contact normal forces are measured apply contact normal forces in parallel directions (e.g., are in the same row of contact structures). As such, probe 58-1 and 58-2 may lie along the same x-y plane (e.g., be coplanar). Surrogate structures 54 (e.g., layer portions 64 in FIG. 5) may flank both sides of sensor probes 58-1 and 58-2 and displace and deflect other contact structures in a similar manner as described in connection with FIG. 8. While not explicitly shown in the cross-sectional view of FIG. 10, device 50 may include some of the same features described in connection with FIGS. 4-8 (e.g., a base or support structure 80, input-output circuitry, processing circuitry, etc.).

If desired, two sensor probes 58-1 and 58-2 and corresponding load cells may be configured to measure two corresponding contact structures 44-2 in the bottom row of connector 32. If desired, the multiple force sensors (e.g., each containing a probe and a corresponding load cell) may measure contact normal forces applied by non-adjacent contact structures 44 (e.g., a central contact structure and two most peripheral contact structures).

FIGS. 9 and 10 are merely illustrative. If desired, any suitable number of probes and load cells may be present in device 50 and may be arranged in various manners to detect contact normal force applied by any suitable combination of contact structures of connector 32.

The foregoing is merely illustrative and various modifications can be made to the described embodiments. The foregoing embodiments may be implemented individually or in any combination.

What is claimed is:

1. A contact force sensing device configured to mate with a port connector having a plurality of conductive contact structures, the contact force sensing device comprising:
a base;
a force sensor on the base configured to measure a force applied by a first conductive contact structure in the plurality of conductive contact structures using a sensor probe that contacts the first conductive contact structure when the sensor probe is inserted into the port connector; and
a mating connector surrogate structure that flanks the sensor probe and is configured to contact at least a second conductive contact structure in the plurality of conductive contact structures when the sensor probe contacts the first conductive contact structure.

2. The contact force sensing device defined in claim 1, wherein the sensor probe comprises a cantilever beam.

3. The contact force sensing device defined in claim 2, wherein the force sensor further comprises a load cell to which the sensor probe is attached.

4. The contact force sensing device defined in claim 3, wherein the plurality of conductive contact structures comprise a plurality of conductive contact pins.

5. The contact force sensing device defined in claim 1, wherein the mating connector surrogate structure is configured to contact each conductive contact structure in the plurality of conductive contact structures other than the first conductive contact structure when the sensor probe contacts the first conductive contact structure.

6. The contact force sensing device defined in claim 1, wherein the plurality of conductive contact structures are arranged in a top row of conductive contact structures and a bottom row of conductive contact structures.

7. The contact force sensing device defined in claim 6, wherein the first conductive contact structure is in the top row.

8. The contact force sensing device defined in claim 7 further comprising:
an additional force sensor on the base configured to measure an additional force applied by a third conductive contact structure in the plurality of conductive contact structures using an additional sensor probe that contacts the third conductive contact structure when the additional sensor probe is inserted into the port connector.

9. The contact force sensing device defined in claim 8, wherein the third conductive contact structure is in the top row.

10. The contact force sensing device defined in claim 8, wherein the third conductive contact structure is in the bottom row.

11. The contact force sensing device defined in claim 1 further comprising:
an output device configured to provide an output indicative of the measured force.

12. The contact force sensing device defined in claim 11, wherein the output device comprises a display and wherein the output comprises a visual output on the display.

13. The contact force sensing device defined in claim 1, wherein the port connector is configured to receive a removable transceiver module.

14. The contact force sensing device defined in claim 1, wherein the port connector is configured to receive a Peripheral Component Interconnect Express (PCIE) connector.

15. Portable test equipment configured to be inserted into an edge card socket having a plurality of conductive contact pins, the portable test equipment comprising:
a support structure;
a force sensor that includes a load cell on the support structure and a sensor probe having a proximal end attached to the load cell and a suspended distal end, wherein the force sensor is configured to detect a contact force applied on the sensor probe by a single conductive contact pin in the plurality of conductive contact pins; and
an edge card surrogate structure configured to engage at least some conductive contact pins in the plurality of conductive contact pins when the single conductive contact pin applies the contact force on the sensor probe.

16. The portable test equipment defined in claim 15, wherein the edge card surrogate structure is coplanar with the sensor probe and is separated from the sensor probe by a gap.

17. The portable test equipment defined in claim 15, wherein the portable test equipment has dimensions that correspond with dimensions of a cage for the edge card socket such that the portable test equipment is pluggable into the cage.

18. The portable test equipment defined in claim 15, wherein the plurality of conductive contact pins are arranged in at least one row of conductive contact pins and wherein the single conductive contact pin is in a central region of the row of conductive contact pins.

19. A handheld connector contact force sensing device receivable by a pluggable transceiver module port of a network device, the handheld connector contact force sensing device comprising:
a support structure;
a force sensor configured to detect a contact normal force applied by a single conductive contact pin in the pluggable transceiver module port; and
a transceiver module surrogate structure configured to engage other conductive contact pins in the pluggable transceiver module port while the force sensor detects the contact normal force.

20. The handheld connector contact force sensing device defined in claim 19 further comprising:
a positioner coupled to and configured to adjust a sensor probe in the force sensor, wherein the contact normal force is applied on the sensor probe when the sensor probe is received in the pluggable transceiver module port.
